(19) United States
(12) Patent Application Publication
(10) Pub. No.: US 2006/0185593 A1
(43) Pub. Date: Aug. 24, 2006

(54) Chemical vapor deposition system and method of exhausting gas from the system

(76) Inventor: Ji-Young Choi, Gyeonggi-do (KR)

Correspondence Address: MARGER JOHNSON & MCCOLLOM, P.C., 210 SW MORRISON STREET, SUITE 400, PORTLAND, OR, 97204, US

(21) Appl. No.: 11/361,086

(22) Filed: Feb. 22, 2006

(30) Foreign Application Priority Data
Feb. 22, 2005 (KR) 2005-14712

(51) Int. Cl. C23C 16/00

(52) U.S. Cl. 118/715; 427/248.1

(57) ABSTRACT

A chemical vapor deposition system is provided. In the chemical vapor deposition system, an amount of a first reaction gas remaining between a process chamber and a first reaction gas supplying unit is exhausted to a vacuum pump, and an amount of a second reaction gas remaining between the process chamber and a second reaction gas supplying unit is exhausted to an absorption pump. In this system, at least two reaction gases which react with each other in the process chamber are separately exhausted, and thus a reaction byproduct is not generated due to a reaction of the gases remaining in the supply lines. Thus, exhaust lines or pumps can be prevented from being damaged due to the reaction byproduct.

### CROSS REFERENCE TO RELATED PATENT APPLICATIONS

This application claims the priority of Korean Patent Application No. 10-2005-0014712, filed on Feb. 22, 2005, in the Korean Intellectual Property Office, the disclosure of which is incorporated herein in its entirety by reference.

### BACKGROUND OF THE INVENTION

1. Field of the Invention

The present invention relates to semiconductor fabricating equipment and, more particularly, to chemical vapor deposition equipment having a divert line and a method of exhausting reaction gases.

2. Description of the Related Art

In a semiconductor fabricating process, a chemical vapor deposition (CVD) technology is mainly used for forming a metal layer on a wafer. However, since the reaction gases being supplied into a chamber using the chemical vapor deposition technology have an extremely low vapor pressure, it is difficult to accurately control a flow rate using an existing mass flow controller (MFC). Accordingly, a divert line is additionally provided on chemical vapor deposition equipment.

Furthermore, in semiconductor fabrication, tungsten is widely used as a metal layer for forming a contact or a via. The metal source gas or reduction gas which is used as reaction gas for depositing a tungsten layer includes tungsten hexafluoride (WF₆) and silicon hydride (SiH₄), or WF₆ and hydrogen (H₂). WF₆ is used as the metal source gas and SiH₄ and H₂ are used as the reduction gases.

The tungsten deposition is classified into a non-selective or Blanket deposition and a selective deposition. The reaction formula of the non-selective deposition is as follows:
WF₆+3H₂->W+6HF (1)

The reaction formula of the selective deposition is as follows:
2WF₆+3SiH₄->2W+3SiF₄+6H₂ (2)
or
WF₆+3H₂->W+6HF (3)

As described above, when depositing tungsten, the divert line is used to accurately control the flow rate. This divert line serves to exhaust remaining gases which are not supplied into a process chamber. The remaining gases may be exhausted to control the flow rate after a process is finished as well as during the process.

Conventionally, the remaining gases are exhausted to a vacuum pump that is used to create a vapor pressure in the chamber through the divert line. When the remaining gases are exhausted to the vacuum pump, the remaining gases react with each other in the vacuum pump, the exhaust line, and the divert line as expressed in formulas 1, 2 and 3 to generate an abundance of very hard metal powder.

The metal powder rapidly accumulates in the vacuum pump, damaging the vacuum pump. Accordingly, in the tungsten depositing process, preventive maintenance of the vacuum pump is frequently needed. If the preventive maintenance is not performed at a suitable time, the vacuum pump is damaged.

### SUMMARY

Chemical vapor deposition system includes a process chamber, a chuck in the process chamber on which a wafer is mounted, a vacuum pump connected to the process chamber and an absorption pump connected to the chuck to hold the wafer on the chuck. The system further includes a first reaction gas supplying line arranged to supply a first reaction gas to the process chamber and a second reaction gas supplying line arranged to supply a second gas to the process chamber. A first divert line is connected to the first reaction gas supplying line and the vacuum pump to exhaust an amount of gas remaining in the first reaction gas supplying line to the vacuum pump. A second divert line is connected to the second reaction gas supplying line and the absorption pump to exhaust an amount of gas remaining in the second reaction gas supply line to the absorption pump.

A method of exhausting reaction gases remaining in supply lines includes holding a wafer on a chuck with an absorption pump, evacuating a process chamber with a vacuum pump, supplying a first reaction gas to the process chamber through a first gas supplying line and supply a second reaction gas to the process chamber through a second gas supplying line. The first and second gases react with each other within the process chamber. The method further includes exhausting an amount of first gas remaining in the first gas supplying line through a first divert line using the vacuum pump and exhausting an amount of second gas remaining in the second gas supplying line through a second divert line using the absorption pump.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic illustration of a chemical vapor deposition system;

FIG. 2 is a schematic illustration of another chemical vapor deposition system;

FIG. 3 is a timing diagram illustrating a supplement of reaction gas when a process is performed in a chemical vapor deposition system; and

FIG. 4 is a flow chart illustrating a method of exhausting gases remaining in a chemical vapor deposition system.

### DETAILED DESCRIPTION

In order to more specifically explain the present disclosure, exemplary embodiments will be described in detail with reference to the attached drawings. However, the present disclosure is not limited to the exemplary embodiments, but may be embodied in various forms. In the figures, if a layer is formed on another layer or a substrate, it means that the layer is directly formed on another layer or a substrate, or that a third layer is interposed therebetween. In the whole following description, the same reference numerals denote the same elements.

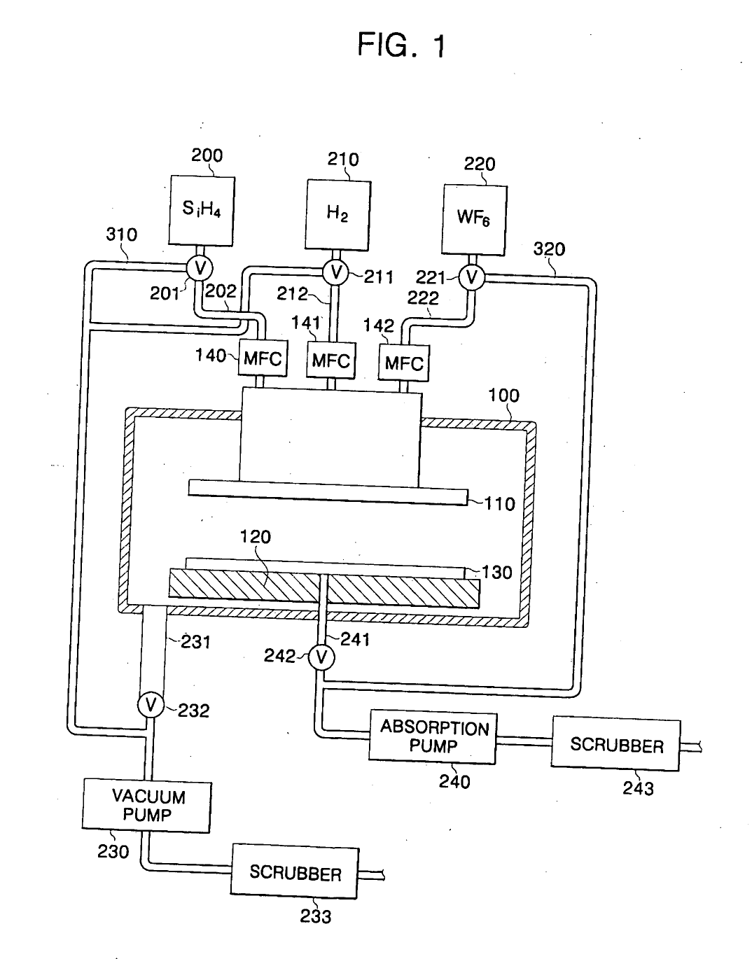

Referring to FIG. 1, a chemical vapor deposition system 105 includes a chamber 100 in which a process is performed. The chamber 100 includes a wafer chuck 120 on which a wafer 130 is mounted. The wafer 130 is carried by a robot arm and mounted on the wafer chuck 120. A heater (not shown) for heating the wafer 130 to a suitable process temperature may be buried in the chuck 120. A shower head 110 for spraying the reaction gases is placed above the wafer chuck 120.

The shower head 110 supplies the gases required for the process onto the wafer in the chamber 100. The reaction gases include a first reaction gas and a second reaction gas. A first gas supplying line for supplying the first reaction gas and a second gas supplying line for supplying the second reaction gas are connected to the shower head 110. The first reaction gas may be a metal source gas or a reduction gas and the second reaction gas may be a metal source gas or a reduction gas.

In the embodiment of FIG. 1, the reaction gas includes the metal source gas and the reduction gas. The metal source gas may include WF₆ and the reduction gas may include SiH₄ and H₂. These gases are used, for example, for tungsten chemical vapor deposition (W-CVD). However, other metal depositing processes may be employed.

FIG. 1 shows a WF₆ supplying unit 220 for supplying the metal source gas into the shower head 110. In addition, a SiH₄ supplying unit 200 and a H₂ supplying unit 210 for supplying the reduction gas are separately provided. Reaction gas supplying lines 202, 212, 222 for connecting the reaction gas supplying units 200, 210, 220 with the shower head 110, respectively, are separately provided.

Moreover, mass flow controllers 140, 141, 142 are connected to the respective reaction gas supplying units. Valves 201, 211, 221 for controlling a supplement of the gases from each respective reaction gas supplying unit 200, 210, 220 are provided on the reaction gas supplying lines 202, 212, 222 connecting the mass flow controllers 140, 141, 142 with the reaction gas supplying units 200, 210, 220. The valves 201, 211, 221 may employ three-path valves.

Although not shown, a purging gas supplying unit may be employed. Purging gas may serve as a carrier gas of the metal source gas and the reduction gas. Alternately, the purging gas may be used for maintaining a process pressure in the chamber 100. Inert gas such as Argon may be used as the purging gas.

Continuing to refer to FIG. 1, a vacuum pump 230 is connected to the chamber 100. The vacuum pump 230 creates a suitable pressure for the process in the chamber 100. The vacuum pump 230 and the chamber 100 are connected to each other by a vacuum line 231. A valve 232 is provided on the vacuum line 231. The valve 232 may employ a throttle valve for controlling a vapor pressure. Alternately, the valve 232 may employ an opening and shutting valve for opening and shutting the vacuum line 231 and the throttle valve.

An absorption pump 240 for holding the wafer 130 on the chuck 120 is connected to the chuck 120 by an absorption line 241. A valve 242 is provided on the absorption line 241. Scrubbers 233, 243 may be provided on the exhaust paths located next to the vacuum pump 230 and the absorption pump 240, respectively. Alternately, any one of the scrubbers 233, 243 may be connected with the vacuum pump 230 and the absorption pump 240.

A first divert line 310 is connected between the vacuum line 231 and the reduction gas supplying lines 202, 212. The first divert line 310 serves to exhaust SiH₄ and H₂, which are amounts of reduction gas remaining in the reduction gas supplying lines 202, 212.

A first end of the reduction gas divert line 310 is individually connected to the valves 201, 211 for controlling a supplement of the reduction gas. A second end of gas divert line 31 is connected to the vacuum pump 230 between the vacuum pump 230 and the valve 232 that is provided on the vacuum line 231. Accordingly, the reduction gas remaining in the reduction gas supplying lines 202 and 212 is exhausted through the vacuum pump 230.

A second divert line 320 is connected between the absorption line 241 and the metal source gas supplying line 222. The second divert line 320 serves to exhaust WF₆, which is an amount of metal source gas remaining in the metal source gas supplying lines 222.

A first end of the metal source gas divert line 320 is connected to the valve 221 for controlling the supplement of the metal source gas. A second end thereof is connected to the absorption pump between the absorption pump 240 and the valve 242 provided on the absorption line 241. Accordingly, the metal source gas remaining in the metal source gas supplying line 222 is exhausted through the absorption pump 240.

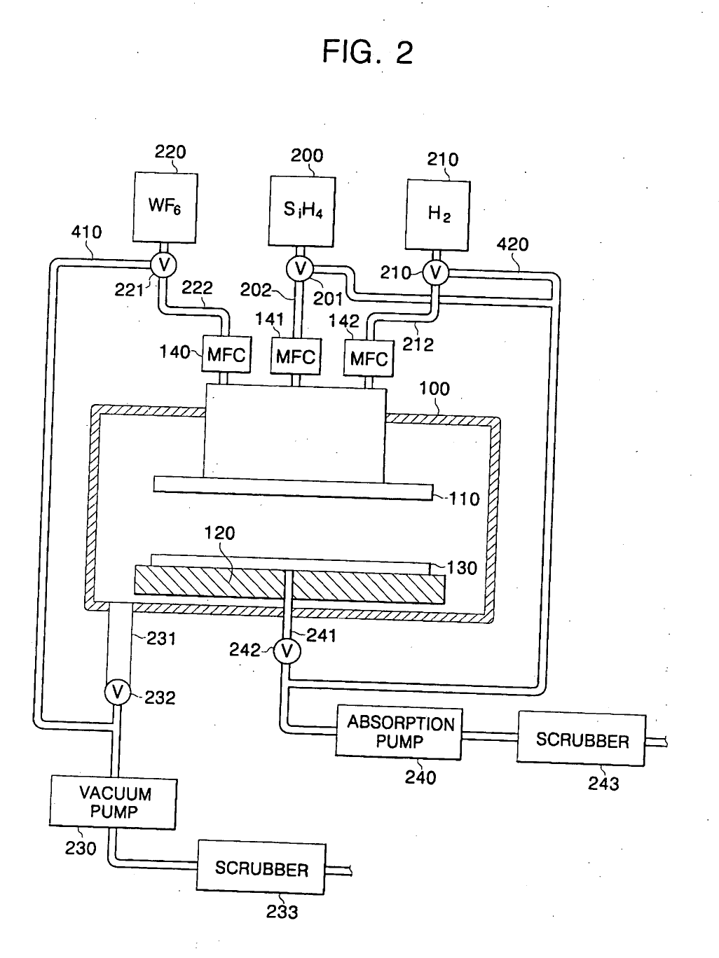

In FIG. 2, the metal source gas and the reduction gas may be exhausted through divert lines opposite to that shown in FIG. 1. That is, a first end of the reduction gas divert line 420 is connected to the valves 201 and 210 for controlling the supplement of the reduction gas, and a second end thereof is connected between the absorption pump 240 and the valve 242 provided on the absorption line 241. A first end of the metal source gas divert line 410 is connected to the valve 221 for controlling the supplement of the metal source gas, and a second end thereof is connected between the vacuum pump 230 and the valve 232 provided on the vacuum line 231.

If the divert lines are connected as described with respect to FIGS. 1 and 2, the metal source gas and the reduction gas are separately exhausted. Accordingly, the metal source gas and the reduction gas are prevented from contacting each other in the pump. Previously, the gases were all exhausted through a single divert line. In that single divert line, the gases would mix and react resulting in the creation of metal powder that would clog the vacuum pump connected to the single divert line. Here, separate gases may be exhausted separately through separate divert lines and corresponding separate pumps. FIGS. 1 and 2 show two separate divert lines, however, three or more divert lines are contemplated to be within the scope of this disclosure. Further, the divert lines shown in FIGS. 1 and 2 are connected to the vacuum pump 230 and the absorption pump 240, which provide a vacuum pressure to exhaust the gases from the divert lines. The divert lines, however, could be connected to other pumps that are or are not connected to the process chamber.

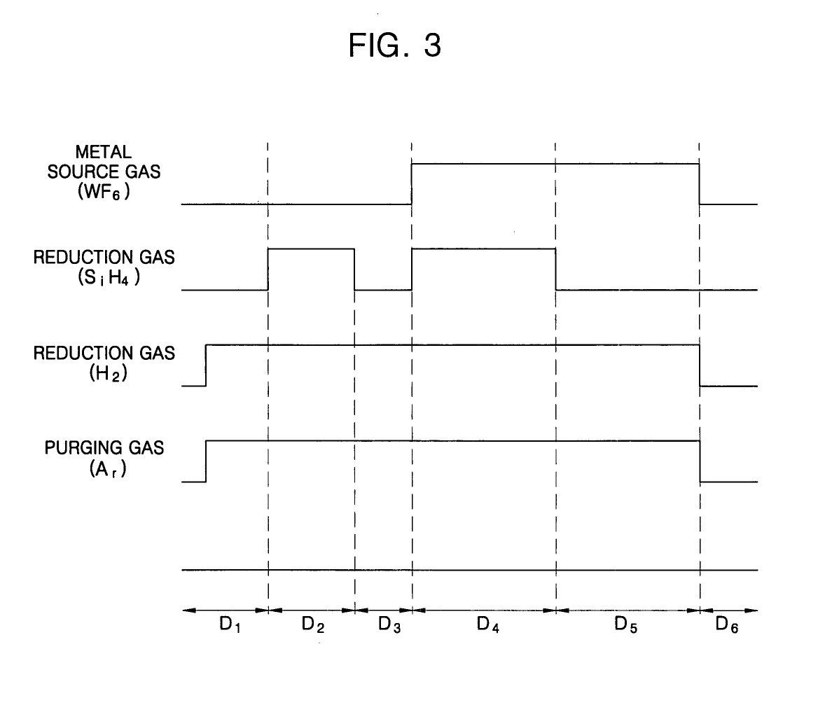

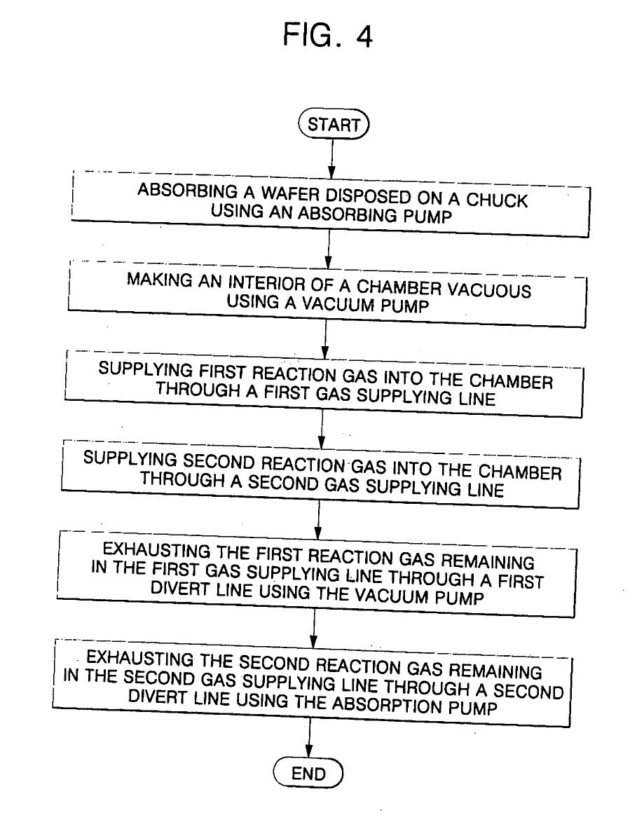

Hereinafter, a method of exhausting gases remaining in a chemical vapor deposition system will be described with reference to FIGS. 1, 3 and 4. FIG. 3 is a timing diagram illustrating gas supplement timing upon selective deposition for tungsten chemical vapor deposition. Although not described, the non-selective deposition may employ the present invention.

The tungsten chemical vapor deposition was schematically described above in and the supplement of the reaction gases and the exhaust of the remaining gases will now be described. Since a temperature, a pressure, and the amount of the gas employed in the process may, if necessary, vary depending on the process, their description will be omitted.

As shown in FIG. 3, H₂ and Ar are continuously supplied from a time that the process starts to a time that the process is finished (D1). At the time that the process starts, the chamber 100 or the wafer 130 is heated to a temperature suitable for the chemical vapor deposition to be performed. The heating may be performed by the heater buried in the chuck 120.

When the chamber 100 or the wafer 130 is heated to the suitable temperature, SiH₄ is injected into the chamber 100 (D2). SiH₄ serves to deposit an amorphous silicon layer on a region at which a tungsten layer will be deposited. This is because the silicon layer efficiently generates tungsten nuclei and prevents attack on a lower layer. However, if the lower layer of the tungsten layer is a layer having bad adhesive force for tungsten, such as titanium or titanium nitride, the silicon layer may not be formed.

When the desired silicon layer is deposited, the supplement of SiH₄ stops. At this time, purging SiH₄ is performed (D3). Alternatively, the supplement of SiH₄ may not stop or the purging may not be performed.

When the supplement of SiH₄ stops and purging is performed, the purged remaining gas is exhausted to the vacuum pump 230. That is, the valve 201 prevents SiH₄ from being supplied to the chamber 100 during purging and connects the reduction gas divert line 310 with the SiH₄ supplying line 202, such that SiH₄ is exhausted through the reduction gas divert line 310 by a pumping force of the vacuum pump 230.

After purging, WF₆ together with SiH₄ is supplied (D4). At this time, the WF₆, SiH₄ and H₂ are all supplied. The SiH₄ rapidly reacts with WF₆ to prevent the attack on the lower layer, and tungsten nuclei are sequentially formed on the lower layer to facilitate tungsten deposition. If a predetermined amount of the tungsten nuclei are formed on the silicon layer, the supplement of SiH₄ stops again.

At this time, purging SiH₄ is performed using the same method as that described above (D5). Tungsten is deposited on a desired portion by WF₆ and H₂, which are continuously supplied. When the tungsten depositing is finished, the supplement of H₂ and WF₆ stops. Then, purging of the metal source gas and the reduction gas is performed (D6).

In the case of WF₆, the valve 221 of the WF₆ supplying line 222 operates to prevent WF₆ from being supplied to the chamber 100 and connects the metal source gas divert line 320 with the WF₆ supplying line 222, such that WF₆ is exhausted through the metal source gas divert line 320 by the pumping force of the absorption pump 240.

In the case of H₂, the valve 211 of the H₂ supplying line 212 operates to prevent H₂ from being supplied to the chamber 100 and connects the reduction gas divert line 310 with the H₂ supplying line 212, such that H₂ is exhausted through the reduction gas divert line 310 by the pumping force of the vacuum pump 230.

In FIG. 2, WF₆ is exhausted to the vacuum pump 230 and the reduction gases such as SiH₄ and H₂ are exhausted to the absorption pump 240.

As a result, the reduction gas and the metal source gas are separately exhausted to the vacuum pump and the absorption pump or the absorption pump and the vacuum pump, respectively. Thus, the metal source gas and the reduction gas can be prevented from contacting each other in the pump and the exhaust line.

As described above, according to the first and second embodiments, since the metal source gas and the reduction gas are exhausted to the vacuum pump and the absorption pump or the absorption pump and the vacuum pump, respectively, a reaction byproduct such as a metal byproduct can be prevented from being generated due to the reaction of the remaining gases in the exhaust lines or the pumps. Thus, the exhaust lines or the pumps can be prevented from being damaged due to the reaction byproduct.

The structure and method for exhausting the remaining gases has relatively high efficiency in the chemical vapor deposition of the semiconductor fabricating process, but may apply to the other semiconductor fabricating process.

1. A chemical vapor deposition system comprising:
a process chamber;
a chuck in the process chamber for mounting a wafer;
a vacuum pump connected to the process chamber;
an absorption pump connected to the chuck to hold the wafer on the chuck;
a first gas supplying line to supply a first reaction gas into the process chamber;
a second gas supplying line to supply a second reaction gas into the process chamber;
a first divert line having a first end connected to the first gas supplying line and a second end connected to the vacuum pump to exhaust the first reaction gas to the vacuum pump; and
a second divert line having a first end connected to the second gas supplying line and a second end connected to the absorption pump to exhaust the second reaction gas to the absorption pump.

2. The system of claim 1, further comprising a first valve for the vacuum pump provided on a path between the vacuum pump and the process chamber.

3. The system of claim 2, wherein the second end of the first divert line is connected between the vacuum pump and the first valve.

4. The system of claim 1, further comprising a second valve for the absorption pump provided on a path between the absorption pump and the process chamber.

5. The system of claim 4, wherein the second end of the second divert line is connected between the absorption pump and the second valve.

6. The system of claim 1, wherein the first reaction gas comprises at least one of SiH₄ and H₂.

7. The system of claim 6, wherein the second reaction gas comprises WF₆.

8. The system of claim 1, wherein the first reaction gas comprises WF₆.

9. The system of claim 8, wherein the second reaction gas is at least one of SiH₄ and H₂.

10. A chemical vapor deposition system comprising:
a process chamber;
a chuck in the process chamber for mounting a wafer;
a vacuum pump connected to the process chamber;
an absorption pump connected to the chuck to hold the wafer on the chuck;
a reduction gas supplying line to supply a reduction gas into the process chamber;
a metal source gas supplying line to supply a metal source gas into the process chamber;
a reduction gas divert line having a first end connected to the reduction gas supplying line and a second end connected to the vacuum pump to exhaust the reduction gas to the vacuum pump; and
a metal source gas divert line having a first end connected to the metal source gas supplying line and a second end connected to the absorption pump to exhaust the metal source gas to the absorption pump.

11. The system of claim 10, wherein the reduction gas comprises at least one of SiH₄ and H₂ and the metal source gas comprises WF₆.

12. The system of claim 10, further comprising a first valve for the vacuum pump provided on a path between the vacuum pump and the process chamber.

13. The system of claim 12, wherein the second end of the reduction gas divert line is connected between the vacuum pump and the first valve.

14. The system of claim 10, further comprising a second valve for the absorption pump provided on a path between the absorption pump and the process chamber.

15. The system of claim 14, wherein the second end of the metal source gas divert line is connected between the absorption pump and the second valve.

16. A chemical vapor deposition system comprising:
a process chamber;
a chuck in the process chamber for mounting wafer;
a vacuum pump connected to the process chamber;
an absorption pump connected to the chuck to hold the wafer on the chuck;
a metal source gas supplying line to supply a metal source gas into the process chamber;
a reduction gas supplying line to supply a reduction gas into the process chamber;
a metal source gas divert line having a first end connected to the metal source gas supplying line and a second end connected to the vacuum pump to exhaust the metal source gas to the vacuum pump; and
a reduction gas divert line having a first end connected to the reduction gas supplying line and a second end connected to the absorption pump to exhaust the reduction gas to the absorption pump.

17. The system of claim 16, wherein the reduction gas comprises at least one of SiH₄ and H₂ and the metal source gas comprises WF₆.

18. The system of claim 16, further comprising a first valve for the vacuum pump provided on a path between the vacuum pump and the process chamber.

19. The system of claim 18, wherein the second end of the metal source gas divert line is connected between the vacuum pump and the first valve.

20. The system of claim 16, further comprising a second valve for the absorption pump provided on a path between the absorption pump and the process chamber.

21. The system of claim 20, wherein the second end of the reduction gas divert line is connected between the absorption pump and the second valve.

22. A method of exhausting gases remaining in a semiconductor fabrication system comprising:
holding a wafer on a chuck using an absorption pump;
evacuating an interior of a process chamber using a vacuum pump;
supplying a first reaction gas into the process chamber through a first gas supplying line;
supplying a second reaction gas into process the chamber through a second gas supplying line;
exhausting an amount of the first reaction gas remaining in the first gas supplying line through a first divert line using the vacuum pump; and
exhausting an amount of the second reaction gas remaining in the second gas supplying line through a second divert line using the absorption pump.

23. The method of claim 22, wherein the first reaction gas comprises at least one of SiH₄ and H₂ and the second reaction gas comprises WF6.

24. The method of claim 22, wherein the first reaction gas comprises WF₆ and the second reaction gas comprises at least one of SiH₄ and H₂.

25. A chemical vapor deposition system comprising:
a first reaction gas supply;
a second reaction gas supply;
a first supply line connected to the first reaction gas supply;
a second supply line connected to the second reaction gas supply;
a first pump;
a second pump separate from the first pump;
a first divert line connected to the first supply line and the first pump; and
a second divert line connected to the second supply line and the second pump.

26. The system of claim 25, further comprising a first valve connected to the first pump, wherein the first divert line is connected between the first valve and the first pump.

27. The system of claim 25, further comprising a second valve connected to the second pump, wherein the second divert line is connected between the second valve and the second pump.
